(19) United States
(12) Patent Application Publication
(10) Pub. No.: US 2003/0121699 A1
(43) Pub. Date: Jul. 3, 2003

(54) Multi-layered printed wiring board having via holes, circuit module comprising circuit elements mounted on the multi-layered printed wiring board, and method of manufacturing the multi-layered printed wiring board

(75) Inventor: Akihiko Happoya, Fussa-shi (JP)

Correspondence Address: Finnegan, Henderson, Farabow,, Garrett & Dunner, L.L.P., 1300 I Street, N.W., Washington, DC, 20005-3315, US

(73) Assignee: KABUSHIKI KAISHA TOSHIBA

(21) Appl. No.: 10/233,518

(22) Filed: Sep. 4, 2002

(30) Foreign Application Priority Data
Dec. 28, 2001 (JP) 2001-401680

(51) Int. Cl. H05K 7/06

(52) U.S. Cl. 174/262; 174/266; 29/852

(57) ABSTRACT

A multi-layered printed wiring board comprising a multi-layered substrate. The substrate has a plurality of conductor layers, a plurality of insulating layers interposed between the conductor layers, a via hole penetrating the insulating layers and having a plated layer electrically connecting the conductor layers, and a plating resist layer through which the via hole passes. The plating resist layer is exposed to an interior of the via hole and divides the plated layer into a plurality of parts. The parts of the plated layer electrically connect the conductor layers.

### CROSS-REFERENCE TO RELATED APPLICATIONS

This application is based upon and claims the benefit of priority from the prior Japanese Patent Application No. 2001-401680, filed Dec. 28, 2001, the entire contents of which are incorporated herein by reference.

### BACKGROUND OF THE INVENTION

1. Field of the Invention

This invention relates to a multi-layered printed wiring board having via holes for electrically connecting a plurality of conductor layers. The invention also relates to a circuit module comprising circuit elements in the multi-layered printed wiring board. The invention further relates to a method for manufacturing the multi-layered printed wiring board

2. Description of the Related Art

Multi-layered printed wiring boards on which circuit elements can be mounted in high density are widely used in electronic apparatuses such as portable computers. The multi-layered printed wiring board has a substrate. The substrate comprises a plurality of conductor layers and a plurality of insulating layers interposed between the conductor layers. Two of the conductor layers are the uppermost and lower most layers of the substrate, while the remaining conductor layers lie in the substrate. The conductors are electrically through at least one via hole.

The via hole penetrates the substrate and extends in the direction of thickness of the substrate. The conductor layer that should be connected are exposed to the via hole. A conductive layer is plated, lining the via hole. Hence, the conductor layers are electrically connected to the plated conductive layer.

In the multi-layered printed wiring board, the via hole for connection the conductor layers penetrates the substrate and extends in the direction of thickness of the substrate. This means that the via hole penetrates not only the conductor layers that should be connected, but also the other conductor layers that need not be connected. As a consequence, the wiring area available in the substrate decreases. That is, wires cannot be formed in some of the wiring area available in the substrate.

Consider a printed wiring board having six conductor layers. The first and sixth conductor layers are the upper most and lowermost layer of the substrate, and the second to fifth conductor layers lie in the substrate. Assume that the first and second conductors must be connected by using a via hole, while the third to the sixth conductor layers need not be connected at all. The via hole penetrates not only the first and second conductor layers, but also the third to sixth conductor layers. Hence, the third to sixth conductor layer are patterned not to be exposed to the via hole. Consequently, the third to sixth conductor layers have their wiring areas reduced, and are restricted in terms of their shapes.

In the case where via holes are used to connect conductor layers, only one circuit can be used for each via hole for the purpose of avoiding short-circuiting. The use of via holes renders it difficult to enhance the wiring density on the multi-layered printed wiring board.

### BRIEF SUMMARY OF THE INVENTION

An object of this invention is provide a multi-layered printed wiring board that can connect the conductor layers constituting a plurality of circuits, by using one via hole.

Another object of the invention is to provide a compact circuit module that comprises this multi-layered printed wiring board.

Still another object of the invention is provide a method of manufacturing the multi-layered printed wiring board that has high wiring density.

To attain the first-mentioned object, a multi-layered printed wiring board according to the present invention comprises a multi-layered substrate. The substrate has a plurality of conductor layers, a plurality of insulating layers interposed between the conductor layers, a via hole penetrating the insulating layers and having a plated layer electrically connecting the conductor layers, and a plating resist layer through which the via hole passes. The plating resist layer is exposed to an interior of the via hole and divides the plated layer into a plurality of parts. The parts of the plated layer electrically connect the conductor layers.

Since the multi-layered printed wiring board is so configured, no areas that cannot be utilized to connect conductor layers by wires are left in multi-layered substrate.

One via hole serves to connect the conductor layers that constitute various types of circuits, unlike in the conventional multi-layered printed wiring board in which one via hole can connect the elements of only one circuit. This remarkably increases the wiring density of the printed wiring board.

Additional object and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given below and the detailed description of the embodiments given below, serve to explain the principles of the invention.

FIG. 1 is a perspective view of a portable computer incorporating a circuit module to which the first embodiment of this invention is applied;

FIG. 2 is a sectional view of the portable computer comprising a housing that contains a circuit module according to the first embodiment of the invention;

FIG. 3 is a sectional view of the multi-layered printed wiring board according to the first embodiment of this invention;

FIG. 4 is a magnified sectional view of part X of FIG. 3;

FIG. 5 is a sectional view of the multi-layered printed wiring board, showing the layers constituting the multi-layered printed wiring board;

FIG. 6 is a sectional view of a part of the first embodiment, illustrating the first to third double copper-clad laminates;

FIG. 7 is a sectional view showing the second double copper-clad laminate of the first embodiment, on which a plating resist layer is formed;

FIG. 8 is a sectional view of the multi-layered printed wiring board, showing the layers put together:

FIG. 9 is a sectional view of the multi-layered printed wiring board having a via hole penetrating all constituent layers;

FIG. 10 is a sectional view of the multi-layered printed wiring board, depicting the via hole lined with a plated layer;

FIG. 11 is a sectional view of a multi-layered printed wiring board according to the second embodiment of the present invention; and

FIG. 12 is a sectional view of a multi-layered printed wiring board according to the third embodiment of this invention.

### DETAILED DESCRIPTION OF THE INVENTION

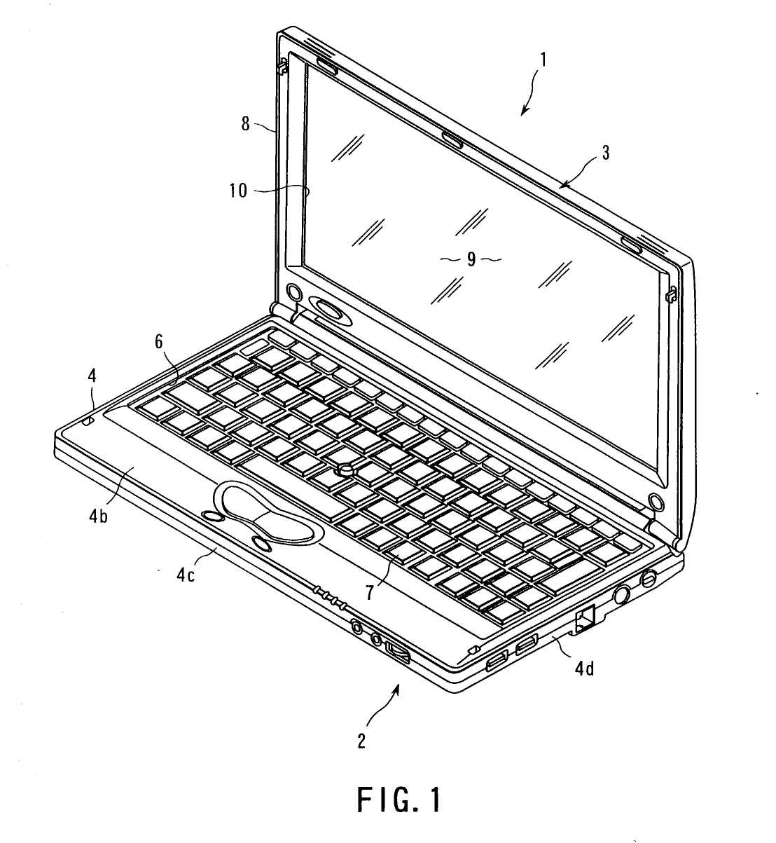

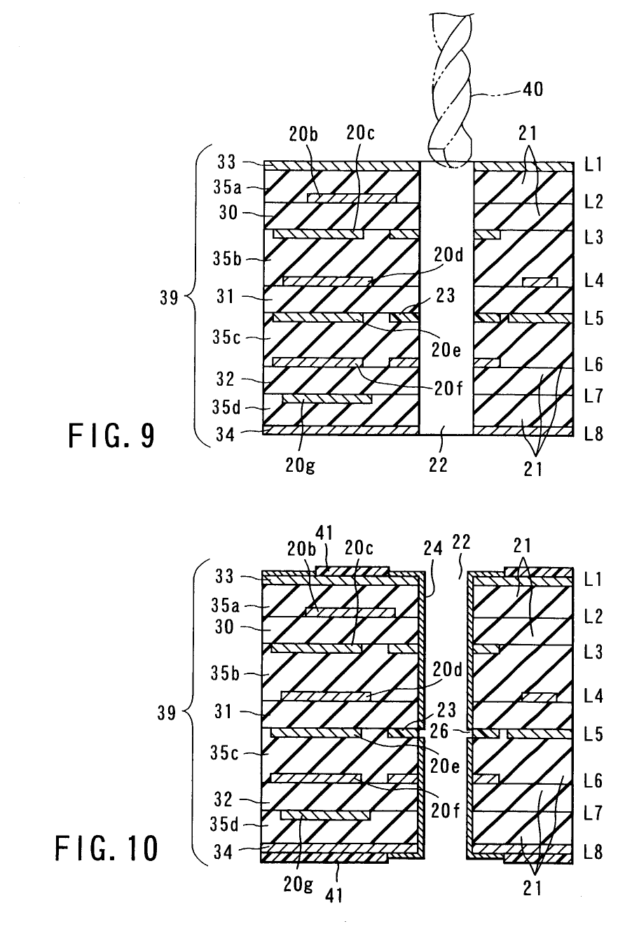

The first embodiment of this invention, which is applied to a portable computer, will be described with reference to FIGS. 1 to 10.

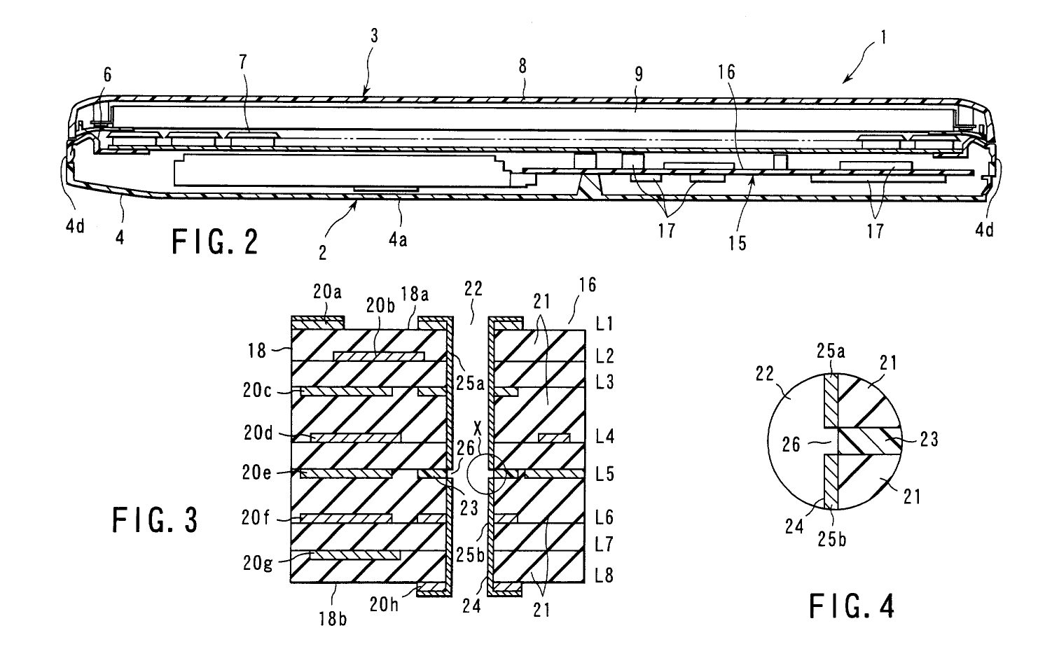

FIGS. 1 and 2 show the portable computer 1 that is an electronic apparatus. The portable computer 1 includes a main part 2 and a display unit 3.

The main part 2 comprises a flat housing 4 shaped like a box. The housing 4 has a bottom wall 4a, a top wall 4b, a front wall 4c, and right and left walls 4d. The top wall 4b has the keyboard attachment section 6. A keyboard 7 is provided in the keyboard attachment section 6.

The display unit 3 comprises a display housing 8 and a liquid crystal display panel 9. The display housing 8 is coupled with the rear edge of the housing 4 by means of hinges (not shown). The liquid crystal display panel 9 is accommodated in the display housing 8 and exposed outside, through the opening 10 made in the front of the display housing 8.

As FIG. 2 depicts, the housing 4 of the main part 2 contains a circuit module 15. The circuit module 15 ha a multi-layered printed wiring board 16 and a plurality of circuit elements 17. The printed wiring board 16 is composed of eight layers. The circuit elements 17 include semiconductor packages and chips. The multi-layered printed wiring board 16 is arranged in parallel to the bottom wall 4a of the housing 4. The circuit elements 17 are mounted both sides of the multi-layered printed wiring board 16.

As shown in FIG. 3, the multi-layered printed wiring board 16 has a multi-layered substrate 18. The substrate 18 has been fabricated by the conventional standard method. The substrate 18 comprises first to eighth conductor layers L1 to L8, or 20a to 20h, and a plurality of insulating layers 21. The conductor layers 20a-20h and the insulating layers 21 are alternately laid, one upon another, in the thickness direction of the multi-layered substrate 18. The multi-layered substrate 18 has a surface 18a and a back surface 18b, which are defined by the uppermost insulating layer 21 and the lowermost insulating layer 21, respectively.

The first to eighth conductor layers 20a to 20h are, for example, copper layers. The first conductor layer 20a, i.e., the first layer L1, is exposed at the surface 18a of the multi-layered substrate 18. The eighth conductor layer 20h, i.e., the eighth layer L8 a layer, is exposed at the back surface 18b of the multi-layered substrate 18. The first and eighth conductor layers 20a and 20h have prescribed patterns. The second to seventh conductor layers 20b to 20g, i.e., layers L2 to L7, are located in the multi-layered substrate 18 and have a prescribed pattern each.

The insulating layers 21 are made of, for example, synthetic-resin material such as polyimide or epoxy resin. Any two adjacent insulating layers 21 clamp a conductor layer between them.

The multi-layered substrate 18 has at least one via hole 22. The via hole 22 extends in the thickness direction of the substrate 18. The via hole 22 penetrates all insulating layers 21 and the first conductor layer 20a, third conductor layer 20c, sixth conductor layer 20f and eighth conductor layer 20h. Thus, the via hole 22 opens at the surface 18a and back surface 18b of the multi-layered substrate 18. The first, third, sixth and eighth conductor layers 20a, 20c, 20f and 20h are exposed to the interior of the via hole 22.

As shown in FIG. 3, the multi-layered substrate 18 has a plating resist layer 23. The plating resist layer 23 is made of synthetic resin such as polyimide-based resin or Teflon-based resin. The plating resist layer 23 is located at the fifth conductor layer 20e, or layer L5, of the multi-layered substrate 18. The layer 23 is interposed between two insulating layers 21 that clamp the fifth conductor layer 20e. Note that the via hole 22 penetrates the plating resist layer 23. Therefore, the plating resist layer 23 is exposed to the interior of the via hole 22.

The via hole 22 is lined with a conductive plated layer 24. The plated layer 24 can readily adhere to the conductor layers 20a, 20c, 20f, and 20h and the insulating layer 21, which were exposed to the interior of a via hole 22. The plated layer 24 can hardly adhere to plating resist layer 23.

This is why the plated layer 24 does not lie at the position where the plating resist layer 23 is provided, as is best seen from FIG. 4. The plating resist layer 23 is exposed to the interior of the via hole 22. Thus, it divides the plated layer 24 into two parts 25a and 25b. The first and second parts 25a and 25b are arranged along the axis of the via hole 22. The plating resist layer 23 defines a gap 26 that separates the first and second parts 25a and 25b of the plated layer 24. The gap 26 is annular, extending along the circumference of the via hole 22. The first and second parts 25a and 25b remain electrically insulated from each other, thanks to the gap 26.

As shown in FIG. 3, the first part 25a of the plated layer 24 lies over the first to fifth layers L1 to L5 of the multi-layered substrate 18. The first part 25a contacts the first conductor layer 20a and the third conductor layer 20c, electrically connecting these conductor layers 20a and 20c.

The second part 25b of the plated layer 24 lies over the fifth to eighth layers L5 to L8 of the multi-layered substrate 18. The second part 25b contacts the sixth conductor layer 20f and the eighth conductor layer 20h, electrically connecting the conductor layers 20f and 20h.

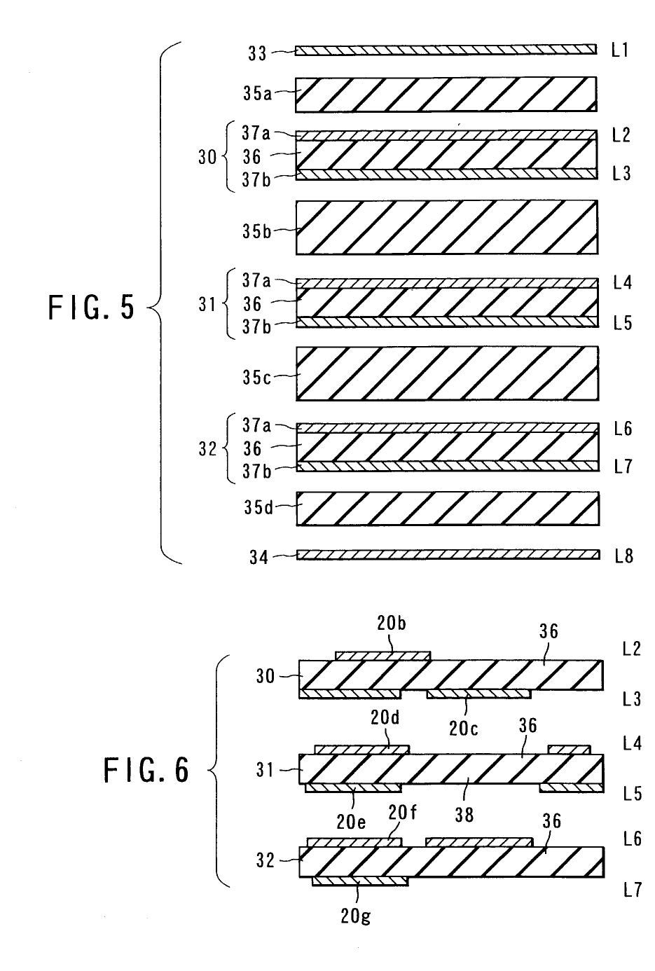

A method of manufacturing the multi-layered printed wiring board 16 will be explained, with reference to FIGS. 5 to 10.

First, first, second and third double copper-clad laminates 30, 31 and 32, two copper layers 33, 34 and a plurality of prepregs 35a to 35d are prepared as is illustrated in FIG. 5. The first double copper-clad laminate 30 will constitute the second and third conductor layers 20b and 20c (L2, L3). The second double copper-clad laminate 31 will constitute the fourth and fifth conductor layers 20d and 20e (L4, L5). The third double copper-clad laminate 32 will constitute the sixth and seventh conductor layers 20f and 20g (L6, L7). The copper layers 33 and 34 are used as the first and eighth conductor layers 20a and 20h, respectively. The prepregs 35a to 35d will constitute insulating layers 21. The first to third double copper-clad laminates 30 to 32 comprises a hard base 36 and two copper layers 37a and 37b each. The hard base 36 is interposed between the copper layers 37a and 37b.

Next, an etching resist is applied to the copper layers 37a and 37b of each of the first to third double copper-clad laminates 30 to 32. The first to third double copper-clad laminates 30 to 32 are etched. The second and third conductor layers 20b and 20c are thereby formed, sandwiching the base 36 of the first double copper-clad laminate 30, as illustrated in FIG. 6. Similarly, the fourth and fifth conductor layers 20d and 20e are formed, sandwiching the base 36 of the second double copper-clad laminate 31. The sixth and seventh conductor layers 20f and 20g are likewise formed, sandwiching the base 36 of the third double copper-clad laminate 32.

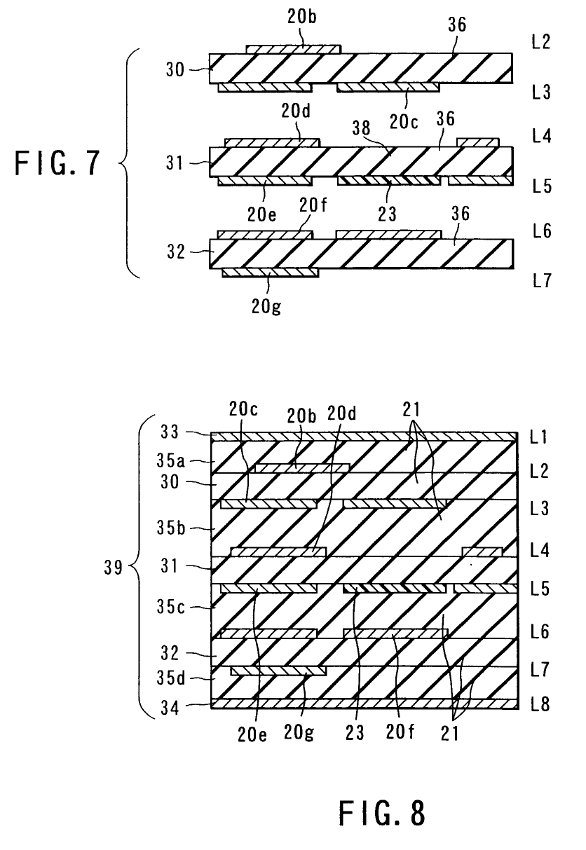

Material that hinders the adhesion of the plated layer is applied by screen printing to that part 38 of the second double copper-clad laminate 31 in which the via hole 22 should be made. The plating resist layer 23 is thereby deposited on the base 36 of the second double copper-clad laminate 31, as shown in FIG. 7.

Next, as shown in FIG. 8, the first to third double copper-clad laminates 30 to 32 and the prepregs 35b and 35c are alternately laid, one on another. The copper layer 33 is laid on the first double copper-clad laminate 30, with the prepreg 35a interposed between the layer 33 and the laminate 30. The copper layer 34 is laid on the third double copper-clad laminate 32, with the prepreg 35d interposed between the layer 34 and the laminate 32. A laminate 39 comprised of eight layers is thereby obtained.

Then, the laminate 39 is heated and pressed by a press (not shown). The prepregs 35a to 35d are left to stand, gradually hardening as time passes. As a result, the first to third double copper-clad laminates 30 to 32 adhere to one another, the first double copper-clad laminate 30 and the copper layer 33 adhere to each other, and the third double copper-clad laminate 32 and the copper layer 34 adhere to each other. The laminate 39 makes an integral structure. Simultaneously, the copper layers 33 and 34 cover the upper surface and lower surface of the laminate 39.

The laminate 39 is set into a drilling machine. The drill 40 of the machine is driven into the laminate 39, passing through the copper layers 33 and 34, all insulating layers 21, the third conductor layer 20c, the sixth conductor layer 20f and the plating resist layer 23. Thus, the via hole 22 is made in the laminate 39.

Next, catalyst (palladium metal) is adsorbed into all surfaces of the laminate 39 and into the inner surface of the via hole 22. Electroless copper plating is performed on the laminate 39. As shown in FIG. 10, a plating resist 41 is applied to the copper layers 33 and 34 that cover the upper and lower surfaces of the laminate 39. The negative patterns corresponding to the first and eighth conductor layers 20a and 20h are thereby formed. Electrolysis copper plating is performed again on the laminate 39. The plated layer 24 is formed on that part of the inner surface of the via hole 22 and those parts of the copper layers 33 and 34, which are not covered with the plating resist 41, as is illustrated in FIG. 10.

At this time, no plated layer adheres to that part of the inner surface of the via hole 22, at which the plating resist layer 23 is exposed. A gap 26 is formed here. The gap 26 divides the plated layer 24 on the inner surface of the via hole 22, into the first and second parts 25a and 25b. These parts 25a and 25b maintain in the via hole 22, electrically insulated from each other.

Thereafter, the plating resist 41 is removed, exposing the copper layers 33 and 34. The copper layers 33 and 34 are etched. The first and eighth conductor layers 20a and 20h are thereby formed on the upper and lower surfaces of the laminate 39, respectively. The structure of FIG. 1 is provided.

Post-process steps, such as character printing and decorative finish, are carried out. Thus, the multi-layered printed wiring board 16 is manufacture.

In the first embodiment of this invention, the plated layer 24 provided in the via hole 22 is divided into first and second parts 25a and 25b that are electrically isolated.

The first part 25a electrically connects the first conductor layer 20 (layer L1) and the third conductor-layer 20c (layer L3). On the other hand, the second part 25b electrically connects the sixth conductor layer 20f (layer L6) and the eighth conductor layer 20h (layer L8).

Therefore, the via hole 22 can serve, in its entirety, to connect the conductor layers. No areas that cannot be utilized to connect conductor layers by wires are left in multi-layered substrate 18.

In the first embodiment, one via hole 22 serves to connect the conductor layers that constitute two types of circuits, unlike in the conventional multi-layered printed wiring board in which one via hole can connect the elements of only one circuit. Hence, when the multi-layered printed wiring board 16 is manufactured by the standard process in which the conductor layers 20a to 20h and the insulating layers 21 are pressed together, not only the multi-layered substrate 18 can be made at low cost and have high quality, thanks to the standard process, but also the wiring density of the printed wiring board 16 remarkably increases.

Since its wiring density increases, the multi-layered printed wiring board 16 can reliably hold, in high density, the circuit elements 17 (e.g., semiconductor packages) that have many terminals to perform many functions. The circuit module 15 can therefore be miniaturized. It follows that the housing 4 containing the circuit module 15 can be made thin. Ultimately, the portable computer 1 can be small and compact.

Furthermore, to manufacture a multi-layered printed wiring board 16 it suffices to apply the material that prevents the adhesion of the plated layer to the second double copper-clad laminate 31 by means of screen printing after the etching on the laminate 31 is completed. Thus, the printed wiring board 16 can be made, utilizing the existing method of manufacturing multi-layered printed wiring boards process, without much changing the existing method. Therefore, the multi-layered printed wiring board 16 can be manufactured with high efficiency, by using the existing production facility.

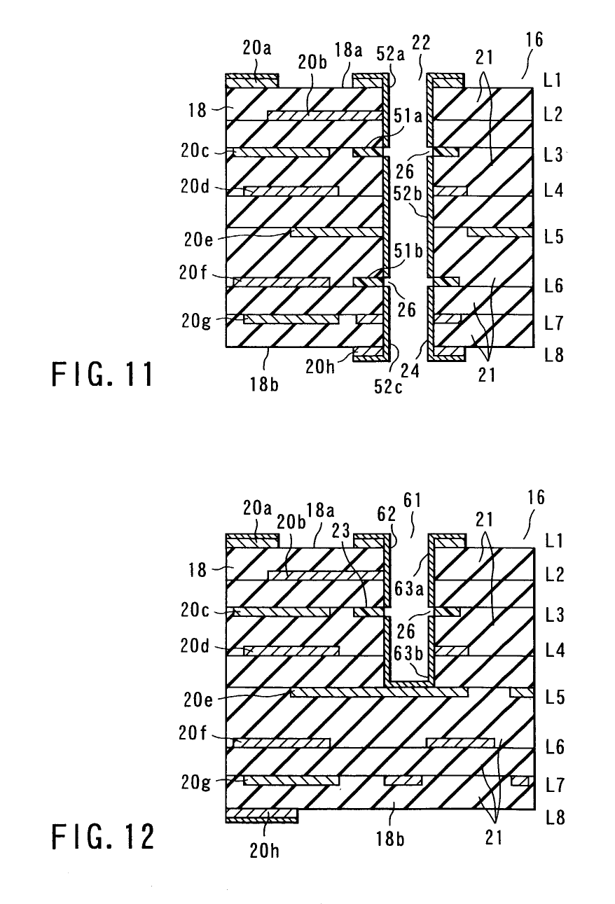

This invention is not limited to the first embodiment described above. FIG. 11 shows the second embodiment of the present invention.

In the second embodiment, two plating resists 51a and 51b are deposited on the two insulating layers 21 of the multi-layered substrate 18, respectively. As in the first embodiment, the plating resists 51a and 51b are made of material that prevents adhesion of plated layers. The plating resists 51a and 51b are spaced apart along the axis of the via hole 22 and exposed to the interior of the via hole 22.

Therefore, no plated layers 24 exist at the positions where the plating resists 51a and 51b lie. The plating resists 51a and 51b divide the plated layer 24 on the inner surface of the via hole 22 into three parts 52a, 52b and 52c. The first, second and third parts 52a, 52b and 52c are spaced apart along the axis of the via hole 22 and are electrically isolated by gaps 26.

As FIG. 11 depicts, the first part 52a of the plated layer 24 lies over the first layer L1 to the third layer L3 of the multi-layered substrate 18. The first part 52a contacts the first conductor layer 20a and second conductor layer 20b, thus electrically connecting these conductor layers 20a and 20b.

The second part 52b of the plated layer 24 lies over the third layer L3 to sixth layer L6 of the multi-layered substrate 18. The second part 52b contacts the fourth conductor layer 20d and fifth conductor layer 20e, electrically connecting these conductor layers 20d and 20e.

The third part 52c of the plated layer 24 lies over the sixth layer L6 to the eighth layer L8 of the multi-layered substrate 18. The third part 52c contacts the seventh conductor layer 20g and eighth conductor layer 20h, electrically connecting these conductor layers 20g and 20h.

In the second embodiment, the plated layer 24 formed on the inner surface of one via hole 22 are divided into three parts, i.e., first part 52a, second part 52b and third part 52c. The three parts 52a, 52b and 52c are electrically insulated from one another. This achieves connection of conductor layers, which constitute three types of circuits, by the use of only one via hole 22.

Furthermore, the via hole 22 serves in its entirety to connect the conductor layers. Therefore, no areas that cannot be utilized to connect conductor layers by wires are left in multi-layered substrate 18, and the wiring density of the printed wiring board 16 further increases.

FIG. 12 illustrates the third embodiment of the invention.

In the third embodiment, the multi-layered substrate 18 has a blind via hole 61. In any other respect, the multi-layered substrate 18 is identical in basic structure to its counterpart of the first embodiment described above.

As FIG. 12 shows, the blind via hole 61 extends through the first layer L1 to fifth layer L5 of the multi-layered substrate 18. The blind via hole 61 opens, at one end, to the surface 18a of the multi-layered substrate 18. The other end of blind via hole 61 is closed by the fifth conductor-layer 20e. A plated layer 62 that is electrically conductive covers the inner surface of the blind via hole 61.

The multi-layered substrate 18 has a plating resist 23 deposited on one of the insulating layers 21. The plating resist 23 is provided in the third layer L3 of the multi-layered substrate 18. The blind via hole 61 penetrates the plating resist layer 23. Therefore, no plated layer exists on that surface part of the blind vie hole 61 which is defined by the plating resist 23. Thus, the plating resist 23 divides the plated layer 62 on the inner surface of the blind via hole 61, into two parts 63a and 63b. The first and second parts 63a and 63b are spaced apart along the axis of the blind via hole 61 and remain mutually insulated electrically by a gap 26.

As FIG. 12 depicts, the first part 63a of the plated layer 62 lies over the first layer L1 to third layer L3 of the multi-layered substrate 18. The first part 63a contacts the first and second conductor layers 20a and 20b, thus connecting these layers 20a and 20b.

The second part 63b of the plated layer 62 lies over the third layer L3 to fifth layer L5 of the multi-layered substrate 18. The second part 63b contacts the fourth conductor layer 20d and fifth conductor layer 20e, electrically connecting these conductor layers 20d and 20e.

In the third embodiment, the plated layer 62 formed on the inner surface of one blind via hole 61 is divided into two parts, i.e., first part 63a and second part 63b that are electrically insulated from each other. Hence, one blind via hole 61 serves to connect two types of circuits.

In the first embodiment described above, the material that prevents adhesion of a plated layer is applied to the second double copper-clad laminate by screen-printing. Nonetheless, the present invention is not limited to the first embodiment. If the material is photosensitive, the plating resist may be formed in two steps. In the first step, a liquefied sensitization agent is applied to the second laminate that has copper layers on both sides, or a photosensitive thin film may be bonded to the second laminate. In the second step, that part of the second laminate that corresponds to the plating resist layer is exposed to light and subsequently developed.

In the first embodiment described above, the multi-layered printed wiring board is formed by means of the standard process. Nevertheless, the invention is not limited to this. For example, the second to seventh layers may be formed by the standard process, and then the first and eighth layers may be formed by build-up method. Alternatively, all layers of a multi-layered printed wiring board may be formed by the build-up method.

Further, the number of layers constituting the multi-layered printed wiring board is not restricted to eight. Rather, the board may comprise six layers, ten layers or more layers. The board can be manufactured in the same way as the first embodiment, regardless of the number of layers it comprises.

Additional advantages and modifications will readily occur to those skilled in the art. Therefore, the invention in its broader aspects is not limited to the specific details and representative embodiments shown and described herein. Accordingly, various modifications may be made without departing from the sprint or scope of the general inventive concept as defined by the appended claims and their equivalents.

What is claimed is:

1. A multi-layered printed wiring board comprising:
a multi-layered substrate having:
a plurality of conductor layers;
a plurality of insulating layers interposed between the conductor layers;
a via hole penetrating the insulating layers and having a plated layer electrically connecting the conductor layers; and
a plating resist layer through which the via hole passes,
wherein the plating resist layer is exposed to an interior of the via hole and divides the plated layer into a plurality of parts, and the parts of the plated layer electrically connect the conductor layers.

2. A multi-layered printed wiring board according to claim 1, wherein the plating resist layer defines gaps in the via hole, and the gaps electrically isolate the parts of the plated layer, each gap being annular and continuously extending along a circumference of the via hole.

3. A multi-layered printed wiring board according to claim 1, wherein the parts of the plated layer oppose one another, with the gaps lying between the parts of the plated layers.

4. A multi-layered printed wiring board according to claim 1, wherein the plating resist layer lies between adjacent insulating layers.

5. A multi-layered printed wiring board according to claim 2, wherein the conductor layers and the insulating layers are alternately laid one upon another, and the parts of the plated layer are arranged in the direction of thickness of the multi-layered substrate.

6. A multi-layered printed wiring board according to claim 1, wherein the via hole penetrates the multi-layered substrate and extends in the direction of thickness of the multi-layered substrate, and the via hole opens, at one end, to a surface of the multi-layered substrate and is opened, at the other end, at a back surface of the multi-layered substrate.

7. A multi-layered printed wiring board according to claim 1, wherein the via hole is a blind via hole which opens, at one end, at a surface of the multi-layered substrate and is closed, at the other end, by one of the conductor layers provided in the multi-layered substrate.

8. A multi-layered printed wiring board according to claim 1, which further comprising an another plating resist layer through which the via hole passes, and the plating resist layers being spaced apart in direction of thickness of the multi-layered substrate,
wherein the plating resist layer and said another plating resist layer are exposed to the interior of the via hole and divide the plated layer into a plurality of parts, and the parts of the plated layer electrically connect the conductor layers.

9. A circuit module comprising:
at least one circuit component; and
a multi-layered printed wiring board including a multi-layered substrate having:
a plurality of conductor layers;
a plurality of insulating layers interposed between the conductor layers;
a via hole penetrating the insulating layers and having a plated layer electrically connecting the conductor layers; and
a plating resist layer through which the via hole passes,
wherein the plating resist layer is exposed to an interior of the via hole and divides the plated layer into a plurality of parts, and the parts of the plated layer electrically connect the conductor layers.

10. A circuit module according to claim 9, wherein the plating resist layer defines gaps in the via hole, and the gaps electrically isolate the parts of the plated layer, each gap being annular and continuously extending along a circumference of the via hole.

11. A circuit module according to claim 9, wherein the conductor layers and the insulating layers are alternately laid one upon another, and the parts of the plated layer are arranged in the direction of thickness of the multi-layered substrate.

12. An electronic apparatus comprising:
a housing; and
a multi-layered printed wiring board provided in the housing and including a multi-layered substrate having:
a plurality of conductor layers;
a plurality of insulating layers interposed between the conductor layers;
a via hole penetrating the insulating layers and having a plated layer electrically connecting the conductor layers; and
a plating resist layer through which the via hole passes,
wherein the plating resist layer is exposed to an interior of the via hole and divides the plated layer into a plurality of parts, and the parts of the plated layer electrically connect the conductor layers.

13. A method of manufacturing a multi-layered printed wiring board having a plurality of conductor layers, a plurality of insulating layers interposed between the conductor layers; a via hole having a plated layer electrically connecting the conductor layers, said method comprising:
depositing the conductor layers and the insulating layers and depositing a plating resist layer at a position where the via hole is to be made, thereby forming a multi-layered substrate;
making the via hole in the multi-layered substrate, said via hole penetrating the conductor layers to be connected, the insulating layers and the plating resist layer; and
performing plating on the multi-layered substrate, forming a plated layer covering an inner surface of the via hole, said plated layer divided by the plating resist layer into parts that are electrically insulated from one another and electrically connecting the conductor layers.

14. A method according to claim 13, wherein the plating resist layer is deposited on one of the insulating layers that have been deposited on the conductor layer, respectively.

15. A method according to claim 13, wherein the plating resist layer is interposed between adjacent two of the insulating layers when the conductor layer and the insulating layers are alternately laid one upon another.

16. A method according to claim 13, wherein the multi-layered substrate is formed by pressing the conductor layers, insulating layers and plating resist layer together after the conductor layers, insulating layers and plating resist layer have been laid one upon another.
